(19) United States
(12) Patent Application Publication
(10) Pub. No.: US 2013/0175431 A1
(43) Pub. Date: Jul. 11, 2013

(54) DETECTOR HAVING LARGE AREA AND METHOD OF MANUFACTURING THE SAME

(71) Applicants: Dae-kun YOON, Daegu (KR); Young KIM, Yongin-si (KR); Jae-chul PARK, Suwon-si (KR); Sang-wook HAN, Busan (KR); Sun-il KIM, Osan-si (KR); Chang-jung KIM, Yongin-si (KR); Jun-su LEE, Seoul (KR)

(72) Inventors: Dae-kun YOON, Daegu (KR); Young KIM, Yongin-si (KR); Jae-chul PARK, Suwon-si (KR); Sang-wook HAN, Busan (KR); Sun-il KIM, Osan-si (KR); Chang-jung KIM, Yongin-si (KR); Jun-su LEE, Seoul (KR)

(73) Assignee: SAMSUNG ELECTRONICS CO., LTD., Suwon-si (KR)

(21) Appl. No.: 13/568,593

(22) Filed: Aug. 7, 2012

(30) Foreign Application Priority Data
Jan. 6, 2012 (KR) 1020120002040

(51) Int. Cl. H01L 27/146; H01L 31/18

(52) U.S. Cl. 250/208.1; 438/73; 257/E31.002

(57) ABSTRACT

A detector includes a substrate; two first regions, each first region having a linear shape, and the two first regions being separated from each other on the substrate and arranged in parallel; and a pixel region provided between the two first regions and including a plurality of pixels, the pixel region including a plurality of second regions perpendicular to the two first regions, each of the two first regions including a peripheral circuit portion, each of the plurality of second regions including a driver line, and a width of each of the plurality of second regions being equal to or less than a width of a single pixel.

### CROSS-REFERENCE TO RELATED APPLICATIONS

This application claims the benefit of Korean Patent Application No. 10-2012-0002040, filed on Jan. 6, 2012, in the Korean Intellectual Property Office, the disclosure of which is incorporated herein in its entirety by reference.

### BACKGROUND

1. Field

One or more example embodiments relate to methods and/or apparatuses for a detector, and more particularly, to a detector having a large two dimensional area, and/or a method of manufacturing the same.

2. Description of the Related Art

Detectors (e.g., image detectors) may be used for various industrial applications in a medical field, a military field, or a semiconductor manufacturing field, etc. A detector having a large two dimensional area may be formed by tiling wafers of a unit size. Thus, the size of a substrate on which a detector is formed may limit the area of a detector.

A pad/peripheral circuit portion may be formed in areas at upper, lower, left, and/or right sides of a wafer of a unit size (hereinafter, referred to as the unit wafer). The pad/peripheral circuit portion may appear as a seam when detected by a detector having a large two dimensional area, due to the area taken by the pad/peripheral circuit portion. The seam generated due to the pad/peripheral circuit portion may become an obstacle to improving image quality of a detector and also increasing an effective area of a detector.

Accordingly, a detector having a large area may be formed by connecting the unit wafers in a 2×2 configuration. In other words, the pad/peripheral circuit portion may be formed in one line each at the upper side and one lateral side of a unit wafer and the unit wafers may be combined at sides where no pad/peripheral circuit portion exists. However, it is difficult to increase the area of a detector any larger without introducing a visible seam in the overall image, and thus, an increase in the area of the detector may be limited.

### SUMMARY

At least one example embodiment provides methods and/or apparatuses for a detector (e.g., an image detector) having a large area that may be easily expanded without introducing a seam in an overall image.

At least one example embodiment provides methods and/or apparatuses for a method of manufacturing the detector having a large area.

Additional aspects will be set forth in part in the description which follows and, in part, will be apparent from the description, or may be learned by practice of example embodiments.

According to at least one example embodiment, a detector having a large area includes a substrate, two first regions, each first region having a linear shape, and the first two regions being separated from each other on the substrate and arranged in parallel, and a pixel region between the two first regions and including a plurality of pixels, the pixel region including a plurality of second regions perpendicular to the two first regions, each of the two first regions including a peripheral circuit portion, each of the plurality of second regions including a driver line, and a width of each of the plurality of second regions being equal to or less than a width of a single pixel.

In at least one example embodiment, the pixel region may include a plurality of unit pixels arranged in an array of two rows and at least one column, and each of the plurality of second regions may be arranged between the at least one column and an adjacent column.

In at least one example embodiment, each of the plurality of unit pixels may be provided with two or more second regions.

In at least one example embodiment, the plurality of unit pixels and the plurality of the first and second regions contacting the plurality of unit pixels may constitute a unit detector, and the unit detectors provided in the first row and the second row may have rotational symmetry.

According to at least one example embodiment, a method of manufacturing a detector having a large area includes forming a plurality of unit detectors, and aligning the plurality of unit detectors on a substrate, wherein forming each of the plurality of the unit detector includes forming a first region including a peripheral circuit portion, forming a second region including a driver line and having a width equal to or less than a width of one pixel, and forming a unit pixel having the first and second regions as two sides perpendicular to each other, and the aligning is performed such that the second region is between two neighboring unit pixels.

In at least one example embodiment, the forming of the plurality of unit detectors may further include forming the plurality of unit detectors on a wafer, and separating the plurality of unit detectors from the wafer.

In at least one example embodiment, the plurality of unit detectors may be arranged in an array of two rows and at least one column.

In at least one example embodiment, the forming of the plurality of unit detectors on a wafer may include transferring a part of each of the plurality of unit detectors to the wafer using a plurality of reticles having different patterns, and repeating the transferring operation.

In at least one example embodiment, the forming of the plurality of unit detectors on a wafer may include transferring a part of each of the plurality of unit detectors to the wafer using a single reticle, and repeating the transferring operation.

In at least one example embodiment, the plurality of unit detectors may be formed using at least two reticles having different patterns.

In at least one example embodiment, a different part of the single reticle may be used to transfer a different part of each of the plurality of unit detectors.

In at least one example embodiment, in the single reticle, a pattern corresponding to the first region of the plurality of unit detectors may be separated from a pattern corresponding to the second region of each of the plurality of unit detectors.

### BRIEF DESCRIPTION OF THE DRAWINGS

These and/or other aspects will become apparent and more readily appreciated from the following description of example embodiments, taken in conjunction with the accompanying drawings in which:

FIG. 1 is a plan view of a detector having a large area according to an example embodiment of inventive concepts;

FIG. 2 is a plan view of a wafer where the unit detector of FIG. 1 is formed;

FIG. 3 illustrates a case in which the unit detector of FIG. 2 is divided into a plurality of sections;

FIGS. 4-7 are plan views of four example reticles used for forming the unit detector of FIG. 3;

FIG. 8 is a plan view of a unit detector formed on a wafer, according to another example embodiment of inventive concepts;

FIG. 9 is a plan view of an example reticle used for forming the unit detector of FIG. 8; and

FIGS. 10 and 11 are plan views of example sixth and seventh reticles used for forming the unit detector of FIG. 8.

### DETAILED DESCRIPTION OF EXAMPLE EMBODIMENTS

Reference will now be made in detail to embodiments, examples of which are illustrated in the accompanying drawings, wherein like reference numerals refer to the like elements throughout. In this regard, example embodiments may have different forms and should not be construed as being limited to the descriptions set forth herein. Accordingly, example embodiments are merely described below, by referring to the figures, to explain aspects of the present description. As used herein, the term “and/or” includes any and all combinations of one or more of the associated listed items.

It will be understood that when an element is referred to as being “connected to” or “coupled to” another element, it can be directly on, connected or coupled to the other element or intervening elements may be present. In contrast, when an element is referred to as being “directly connected to” or “directly coupled to” another element, there are no intervening elements present. Like numbers refer to like elements throughout.

It will be understood that, although the terms first, second, third, etc., may be used herein to describe various elements, components and/or sections, these elements, components and/or sections should not be limited by these terms. These terms are only used to distinguish one element, component or section from another element, component or section. Thus, a first element, component or section discussed below could be termed a second element, component or section without departing from the teachings of example embodiments

The terminology used herein is for the purpose of describing particular embodiments only and is not intended to be limiting. As used herein, the singular forms “a”, “an” and “the” are intended to include the plural forms as well, unless the context clearly indicates otherwise. It will be further understood that the terms “comprises,” “comprising,” “includes,” and/or “including” when used in this specification, specify the presence of stated components, steps, operations, and/or elements, but do not preclude the presence or addition of one or more other components, steps, operations, elements, and/or groups thereof.

Spatially relative terms, such as “below”, “beneath”, “lower”, “above”, “upper”, “between”, and the like, may be used herein for ease of description to describe the relationship of one element or feature to another element(s) or feature(s) as illustrated in the figures. It will be understood that the spatially relative terms are intended to encompass different orientations of the device in use or operation, in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

FIG. 1 is a plan view of a detector having a large two dimensional area according to an example embodiment of inventive concepts. Referring to FIG. 1, a detector includes a base substrate 30 and a plurality of unit detectors 100. The base substrate 30 may be, for example, a printed circuit board (PCB). The unit detectors 100 are aligned on the base substrate 30 in two (2) rows x N columns, where “N” may be 1, 2, 3, 4, . . . , for example, or 10 or higher. In such an alignment, the unit detectors 100 in the same row contact each other and the unit detectors 100 in the same column contact each other. As such, the unit detectors 100 may constitute a detector having a large two dimensional area. The unit detectors 100 arranged in the second row are identical to the unit detectors 100 in the first row and rotated by 180°. That is, the unit detectors 100 in the first and second rows are symmetrically rotated by 180° (i.e., the unit detectors 100 may have rotational symmetry). The shape of each of the unit detectors 100 may be rectangular. Each unit detector 100 includes a pixel region 36 used as a detection region and first and second regions 32 and 34. The pixel region 36 may be a unit pixel region. The pixel region 36 includes a plurality of pixels. The first and second regions 32 and 34 do not include a pixel. The first region 32 may include an input/output pad and a peripheral circuit. For example, the first region 32 may include a circuit for controlling an input/output signal and driving the pixels. The second region 34 includes a row selection and a driver line. The second region 34 may include a flip-flop generating a signal for selecting pixels of the pixel region 36 in a row direction, and a driver for transmitting the signal to a row metal line. The first and second regions 32 and 34 may be perpendicular to each other and one end of each region may contact each other.

In the unit detector 100, the first region 32 is provided as a horizontal line at the upper side of the pixel region 36 and the second region 34 is provided as a vertical line at the right side of the pixel region 36. When the unit detector 100 is provided at the second row, the first region 32 is provided as a horizontal line at the lower side of the pixel region 36 and the second region 34 is provided as a vertical line at the left side of the pixel region 36. The width t1 of the second region 34 may be, for example, equal to or less than the width of one pixel in the pixel region 36. Accordingly, the second region 34 may be small enough so as not to be detected. Thus, the detector may reduce (or alternatively, prevent) the seam from appearing on an overall screen, which has been a problem in conventional detectors , As such, a detection area of the detector may be increased without the presence of a visible seam. In the same row, the second region 34 contacts the pixel region 36 of the neighboring unit detector 100. Also, the first regions 32 of the respective unit detectors 100 are connected to one another forming a single line. As such, the unit detectors 100 in the same row may be continuously connected to one another such that the two dimensional area of the detector may be increased without making a seam.

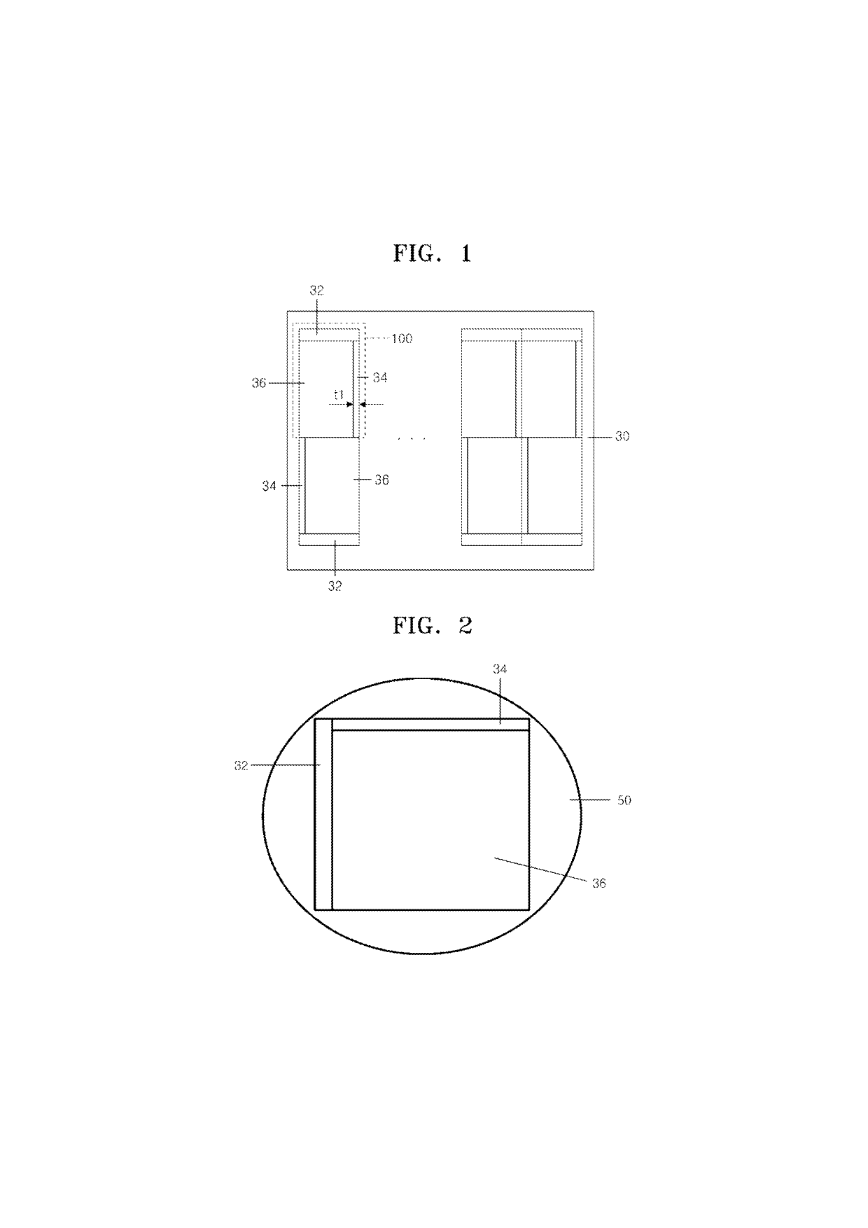

FIG. 2 is a plan view of a wafer 50 where the unit detector 100 of FIG. 1 is formed. For convenience of explanation, illustration of a flat zone is omitted from the wafer 50.

As illustrated in FIG. 2, the unit detector 100 may be formed on one unit of the wafer 50. That is, one unit detector may be formed on one unit of the wafer 50. After the unit detector 100 is formed on the wafer 50, the unit detector 100 is separated from the wafer 50 through a cutting process. The unit detector 100 formed as above is aligned on the base substrate 30 so that a detector having a large two dimensional area may be easily formed.

Next, a method of manufacturing the unit detector 100 on the wafer 50 of FIG. 2 is described below.

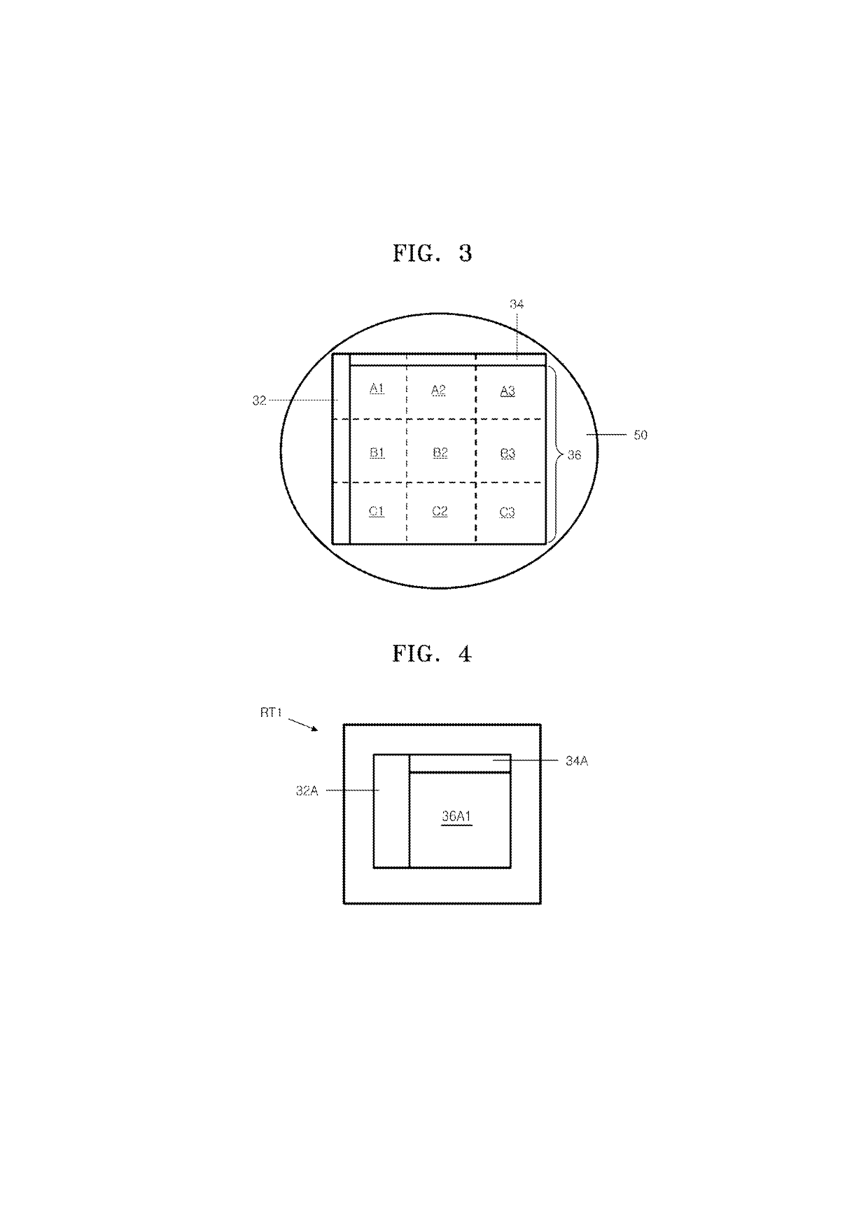

FIG. 3 illustrates a case in which the unit detector 100 of FIG. 2 is divided into a plurality of sections. In FIG. 3, for convenience of explanation, the unit detector 100 is divided into three rows and three columns. However, example embodiments are not limited thereto. Horizontal and vertical dotted lines are hypothetical lines for dividing the unit detector 100.

An area A1 at the first row and first column of the unit detector 100 formed on the wafer 50 includes part of the pixel region 36, part of the first region 32, and part of the second region 34. An area B1 at the second row and first column and an area C1 at the third row and first column are identical to each other, and each area includes part of the pixel region 36 and part of the first region 32. An area A2 at the first row and second column and an area A3 at the first row and third column are identical to each other, and each area includes part of the pixel region 36 and part of the second region 34. Areas B2, B3, C2, and C3 at the second row and second column, second row and third column, third row and second column, and third row and third column are identical to one another, and each area includes part of the pixel region 36. The area A1 at the first row and first column is formed by using a first reticle RT1 of FIG. 4.

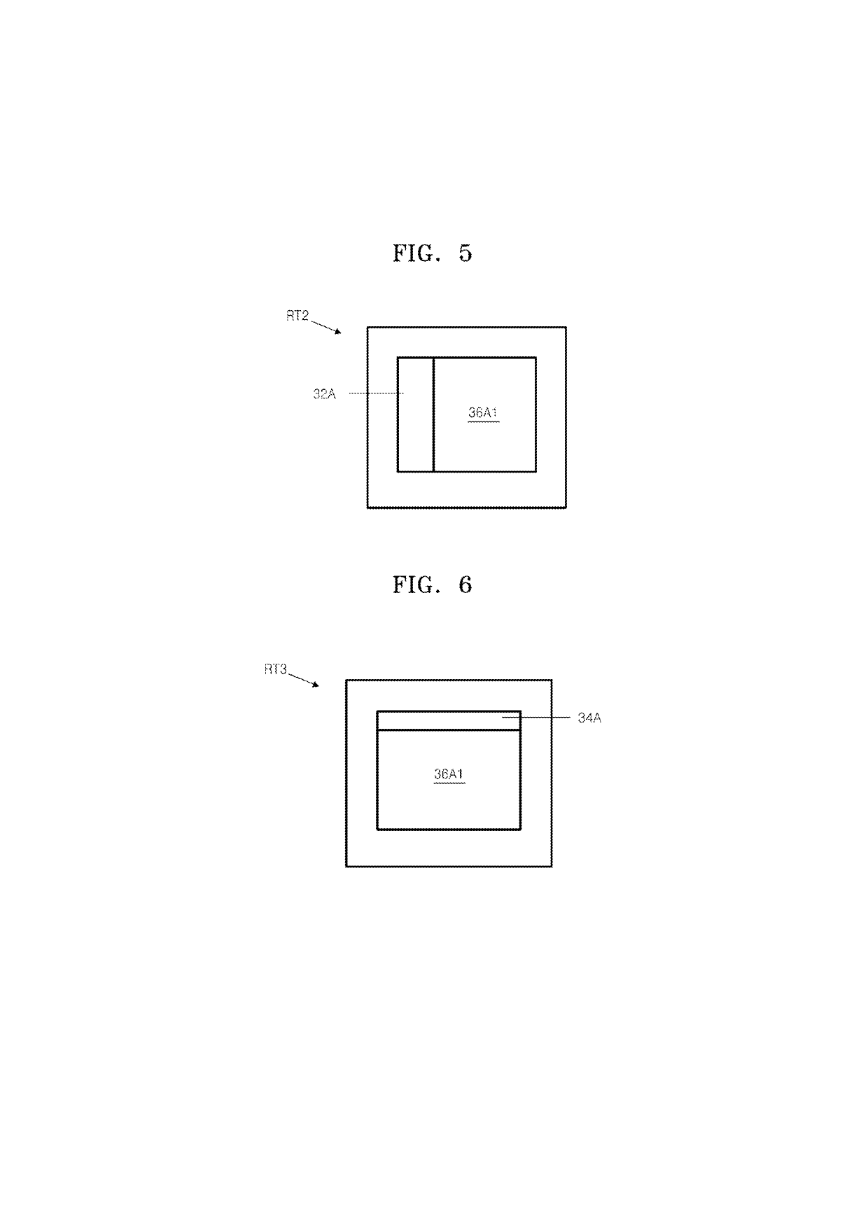

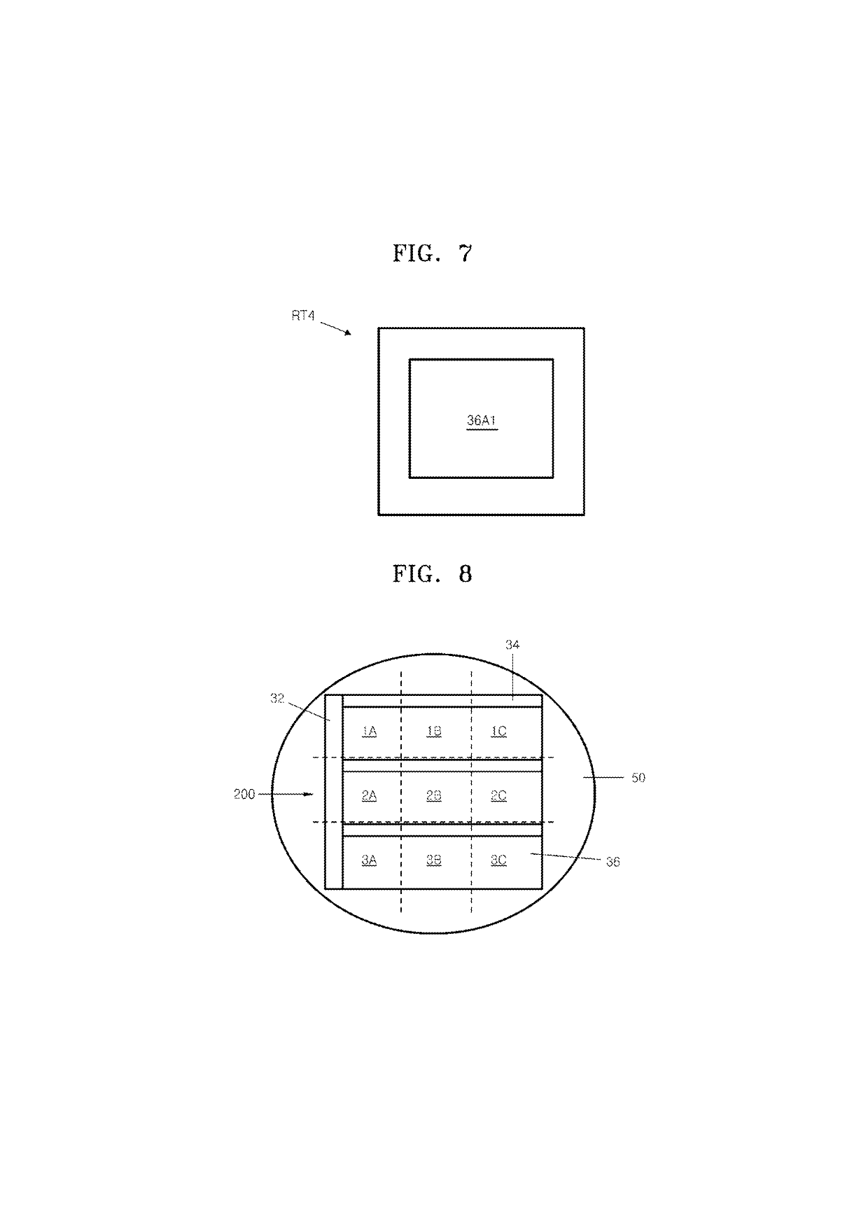

Referring to FIG. 4, the first reticle RT1 includes a first pattern region 32A, a second pattern region 34A, and a first pixel region pattern 36A1. The first reticle RT1 is aligned to the area A1 of the wafer 50 and then exposure is performed through the first reticle RT1. Thus, the patterns 32A, 34A, and 36A1 formed on the first reticle RT1 are transferred to the area Al of the wafer 50 of FIG. 3 so that the area A1 at the first row and first column is formed on the wafer 50. The areas A2, A3, B1-B3, and C1-C3 of the unit detector 100 of the wafer 50 may be formed in the same manner. However, a second reticle RT2 of FIG. 5 is used for forming the areas B1 and C1 at the second and third rows and first column. A third reticle RT3 of FIG. 6 is used for forming the areas A2 and A3 at the first row and second and third columns. A fourth reticle RT4 of FIG. 7 is used for forming the other areas B2, B3, A2, and A3. The unit detector 100 of FIG. 3 may be formed by sequentially forming the areas A1-A3 at the first row and the areas B1-B3 and C1-C3 at the second and third rows. Alternatively, the unit detector 100 of FIG. 3 may be formed by sequentially forming the areas A1, B1, and C1 at the first column and the areas A2, B2, and C2, and A3, B3, and C3 at the second and third columns. This method may be applied to forming a unit detector 200 of FIG. 8.

FIG. 8 is a plan view of the unit detector 200 formed on the wafer 50, according to another example embodiment. Referring to FIG. 8, the structure of the unit detector 200 is similar to that of the unit detector 100 of FIG. 1, except for a plurality of second regions 34 provided in parallel between the pixel regions 36. Each of the second regions 34 is arranged to be perpendicular to the first region 32 and has one end contacting the first region 32. The unit detector 200 configured as above may be formed by the method used for the unit detector 100 of FIG. 3. In FIG. 8, horizontal and vertical dotted lines are hypothetical lines for dividing the unit detector 200 in a matrix. The configuration of the areas 1A-3A at the first to third rows and first column may be the same as the area A1 of FIG. 3. The configuration of the areas 1B, 1C, 2B, 2C, 3B, and 3C at the first to third rows and second and third columns may be the same as the areas A2 or A3 of FIG. 3.

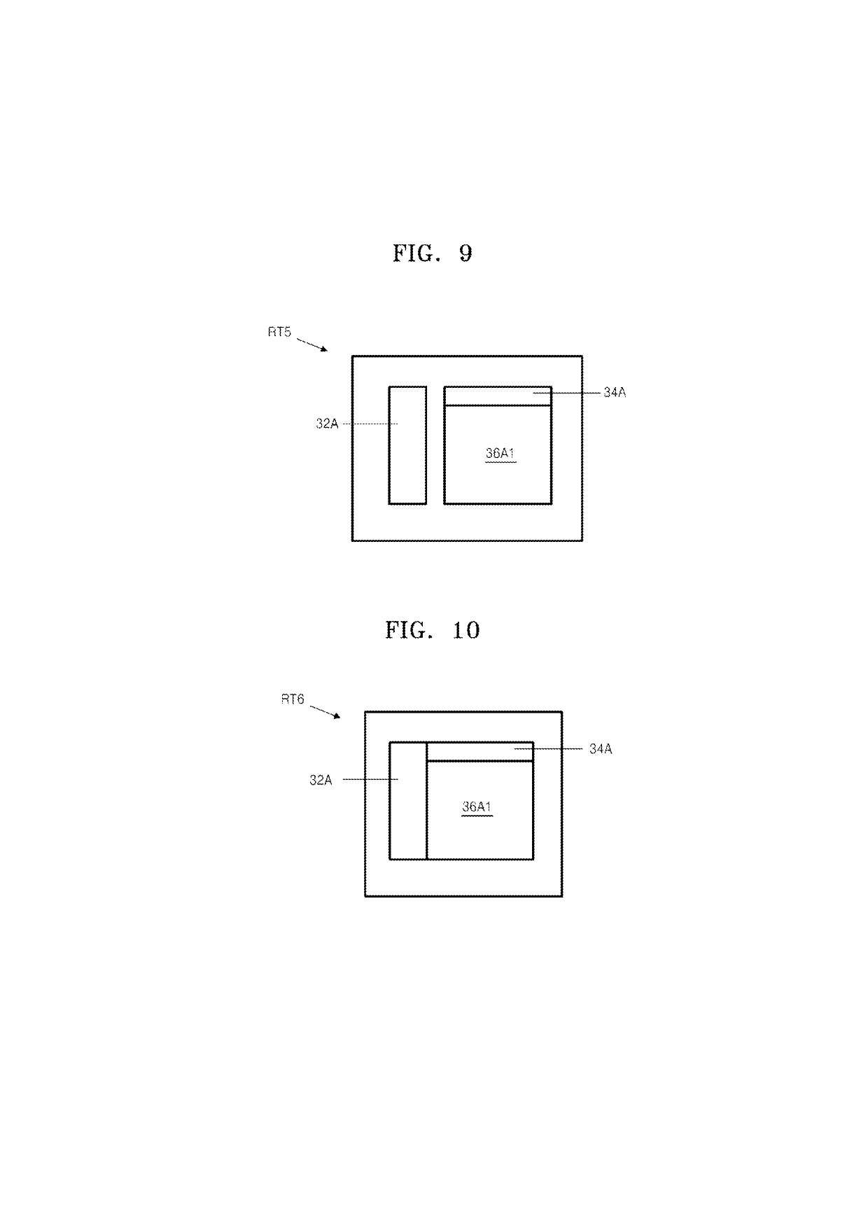

The respective areas of the unit detector 200 of FIG. 8 may be formed by using a fifth reticle RT5 of FIG. 9. Referring to FIG. 9, the fifth reticle RT5, like the first reticle RT1, includes the first and second pattern regions 32A and 34A and the first pixel region pattern 36A1. However, unlike the first reticle RT1, the first pattern region 32A is separated from the second pattern region 34A and the first pixel region pattern 36A1. If part of the first region 32 included in the areas 1A-3A at the first to third rows and first column of FIG. 8 is to be formed by using the fifth reticle RT5, then the second pattern region 34A and the first pixel region pattern 36A1 of the fifth reticle RT5 are light-shielded for use. That is, only the first pattern region 32A is used for transfer. Also, when parts of the pixel region and the second region 34 included in the area 1A-3A at the first to third rows and first column of FIG. 8 and the areas 1B, 1C, 2B, 2C, 3B, and 3C at the first to third rows and second and third columns of FIG. 8 are to be formed, the first pattern region 32A of the fifth reticle RT5 is light-shielded for use.

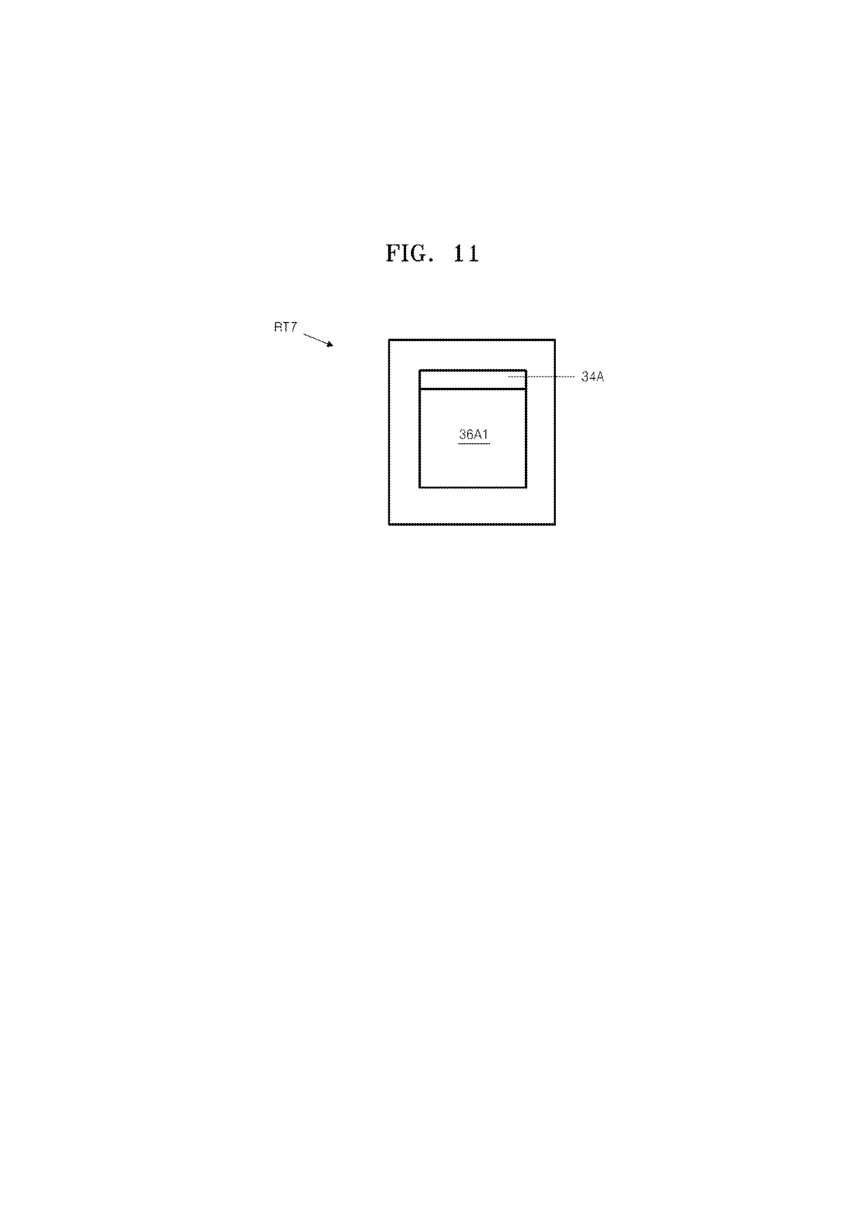

As such, although the unit detector 200 of FIG. 8 may be formed by using only the fifth reticle RT1 of FIG. 9, it may be formed by using two reticles such as sixth and seventh reticles RT6 and RT7 of FIGS. 10 and 11.

In detail, the sixth reticle RT6 of FIG. 10 may be identical to the first reticle RT1 of FIG. 4. The sixth reticle RT6 of FIG. 10 may be used to form the areas 1A-3A at the first to third rows and first column of FIG. 8. The seventh reticle RT7 of FIG. 11 may be identical to the third reticle RT3 of FIG. 6. The seventh reticle RT7 of FIG. 11 may be used to form the other areas 1B, 1C, 2B, 2C, 3B, and 3C at the first to third rows and second and third columns of FIG. 8.

As described above, a detector having a large area according to inventive concepts includes a plurality of unit detectors and each unit detector includes a pad and peripheral circuit portion (first region) of one row (column) and selection and driver lines (second region) of one column (row). By connecting the unit detectors such that the first region has a linear shape, a 2-D array is obtained and the overall two dimensional area of the unit detector may be easily increased.

Also, since the width of the selection and driver line (i.e., the second region) is formed to be equal to or less than the width of one pixel, the unit detector may be reduce (or alternatively, prevent) a visible seam. Thus, an effective two dimensional area of the unit detector may be increased.

It should be understood that the exemplary embodiments described herein should be considered in a descriptive sense only and not for purposes of limitation. Descriptions of features or aspects within each example embodiment should typically be considered as available for other similar features or aspects in other example embodiments.

What is claimed is:

1. A detector comprising:
a substrate;
two first regions, each first region having a linear shape, and the two first regions being separated from each other on the substrate and arranged in parallel; and
a pixel region provided between the two first regions and including a plurality of pixels, the pixel region including a plurality of second regions perpendicular to the two first regions, each of the two first regions including a peripheral circuit portion, each of the plurality of second regions including a driver line, and a width of each of the plurality of second regions being equal to or less than a width of a single pixel.

2. The detector of claim 1, wherein the pixel region includes a plurality of unit pixels in an array of two rows and at least one column, and each of the plurality of second regions is arranged between the at least one column and an adjacent column.

3. The detector of claim 2, wherein each of the plurality of unit pixels has two or more second regions.

4. The detector of claim 2, wherein the plurality of unit pixels and the plurality of the first and second regions contact the plurality of unit pixels and constitute a unit detector, and the unit detectors provided in the first row and the second row have rotational symmetry.

5. A method of manufacturing a detector, the method comprising:
forming a plurality of unit detectors; and
aligning the plurality of unit detectors on a substrate, wherein
forming a plurality of unit detectors includes:
forming a first region including a peripheral circuit portion;
forming a second region including a driver line, the second region having a width equal to or less than a width of one pixel; and
forming a unit pixel having the first and second regions on two sides of the unit pixel, the first and second regions being perpendicular to each other, and
the aligning is performed such that the second region is between two neighboring unit pixels.

6. The method of claim 5, wherein the forming of the plurality of unit detectors further includes:
forming the plurality of unit detectors on a wafer; and
separating the plurality of unit detectors from the wafer.

7. The method of claim 5, wherein the plurality of unit detectors are arranged in an array of two rows and at least one column.

8. The method of claim 6, wherein the forming of the plurality of unit detectors on a wafer includes:
transferring a part of each of the plurality of unit detectors to the wafer using a plurality of reticles having different patterns; and
repeating the transferring operation.

9. The method of claim 6, wherein the forming of the plurality of unit detectors on a wafer includes:
transferring a part of each of the plurality of unit detectors to the wafer using a single reticle; and
repeating the transferring operation.

10. The method of claim 8, wherein the plurality of unit detectors are formed using at least two reticles, each reticle having different patterns.

11. The method of claim 9, wherein a different part of the single reticle is used to transfer a different part of each of the plurality of unit detectors.

12. The method of claim 9, wherein, in the single reticle, a pattern corresponding to the first region of the plurality of unit detectors is separated from a pattern corresponding to the second region of each of the plurality of unit detectors.
